(19) United States
(12) Patent Application Publication
(10) Pub. No.: US 2026/0372100 A1
(43) Pub. Date: Nov. 19, 2026

(54) STACKED PACKAGE STRUCTURE AND PREPARATION METHOD THEREFOR

(71) Applicant: Forehope Electronic (Ningbo) Co., Ltd., Ninbho City (CN)

(72) Inventors: Zhenghong HE, Ningbo City (CN); Lei Zhong, Ningbo City (CN); Li LI, Ningbo City (CN); Yupeng Xu, Ningbo City (CN)

(21) Appl. No.: 19/340,126

(22) Filed: Sep. 25, 2025

(30) Foreign Application Priority Data
May 14, 2025 (CN) 202510616485.5

(51) Int. Cl. H10W 42/00; H10W 40/22; H10W 70/00; H10W 70/05; H10W 70/65; H10W 70/685; H10W 74/01; H10W 74/10; H10W 74/15; H10W 90/00

(52) U.S. Cl. CPC H10W 42/121; H10W 40/228; H10W 70/05; H10W 70/099; H10W 70/65; H10W 70/685; H10W 74/012; H10W 74/016; H10W 74/117; H10W 74/121; H10W 74/15; H10W 90/401; H10W 90/701; H10W 90/724; H10W 90/734

(57) ABSTRACT

The present disclosure provides a stacked package structure and a preparation method therefor, relating to the technical field of chip packaging. The stacked package structure includes a first substrate, a first chip, a second substrate, and an encapsulation layer, wherein the first chip is attached to the first substrate; the second substrate is spaced apart and arranged on one side of the first chip away from the first substrate, and a bonding solder ball is arranged on one side of the second substrate close to the first substrate; the encapsulation layer is arranged between the first substrate and the second substrate; the first groove is arranged in the first substrate; and the second groove is arranged in the second substrate.

### CROSS-REFERENCE TO RELATED APPLICATION

The present disclosure claims priority to Chinese patent Application No. 202510616485.5, filed with the Chinese Patent Office on May 14, 2025, entitled “STACKED PACKAGE STRUCTURE AND PREPARATION METHOD THEREFOR”, the whole contents of which are incorporated herein by reference.

### TECHNICAL FIELD

The present disclosure relates to the technical field of chip packaging, and specifically to a stacked package structure and a preparation method therefor.

### BACKGROUND ART

With the rapid development of the semiconductor industry, electronic products are becoming increasingly miniaturized and densified. Communication devices need to meet high bandwidth performance, and are widely used in the semiconductor industry by POP (package on package) structure. The memory chip and processor chip are packaged together by the POP structure, so as to meet the high bandwidth performance and realize miniaturization. The packaged product has advantages of smaller size, superior product performance, and faster signal transmission frequency, etc. The product is mainly applied in communication terminal products, which are miniaturized and thinned.

The traditional POP structure adopts different materials for different package bodies, and the CTE coefficients between materials are also different. During the reflow soldering process of the product, warpage of the product is likely to occur, which may result in bridging or false soldering between solder balls (intermediate layer solder balls and solder balls at the bottom of the substrate). The stacked structure formed by soldering with an adapter plate requires the formation of solder balls on the adapter plate, and the surface bonding pad of the substrate is soldered by the solder balls. However, warpage of the substrate is easy to occur, which may result in bridging between the solder balls, thereby affecting the electrical connection performance. Moreover, in a conventional encapsulation layer, the fluidity of the encapsulating material is limited, which results in a poor filling effect, and voids are easily formed, thereby affecting the performance of the product.

### SUMMARY

The embodiments of the present disclosure provide a stacked package structure, including:
a first substrate;
a first chip, wherein the first chip is attached to the first substrate;
a second substrate, wherein the second substrate is spaced apart on one side of the first chip away from the first substrate; a bonding solder ball is arranged on one side of the second substrate close to the first substrate; and the bonding solder ball is connected to the first substrate; and
an encapsulation layer, wherein the encapsulation layer is arranged between the first substrate and the second substrate, and is coated outside the first chip and the bonding solder ball.

At least two sides of the first chip are provided with the bonding solder balls; a first groove is arranged on one side of the first substrate close to the second substrate; a second groove is arranged on one side of the second substrate close to the first substrate; the first groove and the second groove are both located on one side of the bonding solder ball away from the first chip; and the encapsulation layer is filled into the first groove and the second groove.

### BRIEF DESCRIPTION OF DRAWINGS

In order to more clearly illustrate the technical solutions of the embodiments of the present disclosure, a brief introduction of the drawings required for the embodiments is provided below. It should be understood that the following drawings merely illustrate certain embodiments of the present disclosure and should not be regarded as limiting the scope thereof. For those of ordinary skill in the art, other related drawings may also be obtained based on these drawings without creative efforts.

FIG. 1 shows a schematic diagram of a stacked package structure provided by one embodiment of the present disclosure;

FIG. 2 shows a partially enlarged schematic diagram at II in FIG. 1;

FIG. 3 shows a process flow diagram of a preparation method of a stacked package structure provided by one embodiment of the present disclosure;

FIG. 4 shows a process flow diagram of a preparation method of a stacked package structure provided by one embodiment of the present disclosure;

FIG. 5 shows a process flow diagram of a preparation method of a stacked package structure provided by one embodiment of the present disclosure;

FIG. 6 shows a schematic diagram of a stacked package structure provided by another embodiment of the present disclosure;

FIG. 7 shows a top view of a stacked package structure provided by another embodiment of the present disclosure;

FIG. 8 shows a schematic diagram of a stacked package structure provided by another embodiment of the present disclosure;

FIG. 9 shows a schematic diagram of a stacked package structure provided by another embodiment of the present disclosure;

FIG. 10a shows a schematic diagram of a stacked package structure provided by another embodiment of the present disclosure;

FIG. 10b shows a preparation process flow diagram of a stacked package structure provided by another embodiment of the present disclosure;

FIG. 11 shows a schematic diagram of a stacked package structure provided by another embodiment of the present disclosure;

FIG. 12 shows a partially enlarged schematic diagram at XII in FIG. 11;

FIG. 13 shows a schematic diagram of a stacked package structure provided by another embodiment of the present disclosure;

FIG. 14 shows a process schematic diagram of step S6 in another embodiment of the present disclosure;

FIG. 15 shows a schematic diagram of a stacked package structure provided by another embodiment of the present disclosure;

FIG. 16 shows a schematic diagram of a stacked package structure provided by another embodiment of the present disclosure.

Reference numbers: 100-stacked package structure; 110-first substrate; 111-first groove; 112-combined circuit layer; 113-first solder mask layer; 114-connection solder ball; 115-first pad; 116-first extension groove; 117-support pad; 120-first chip; 130-second substrate; 131-second groove; 132-second solder mask layer; 133-insulation layer; 134-third solder mask layer; 135-second pad; 136-third groove; 137-second extension groove; 138-through hole; 139-blocking groove; 140-encapsulation layer; 150-bonding solder ball; 151-inner copper ball; 152-outer tin layer; 160-heat dissipation post; 161-first clearance opening; 162-second clearance opening; 163-third clearance opening; 164-fourth clearance opening; 170-second chip; 200-protective film.

### DETAILED DESCRIPTION OF EMBODIMENTS

In order to make the objectives, technical solutions, and advantages of the embodiments of the present disclosure clearer, the technical solutions in the embodiments of the present disclosure will be described clearly and completely as follows in conjunction with drawings in the embodiments of the present disclosure. It is clear that the embodiments described are only partial embodiments of the present disclosure, and not all of the embodiments. The assembly in embodiments of the present disclosure, generally described and shown in the drawings herein, can be arranged and designed in various configurations.

Therefore, the following detailed description of the embodiments of the present disclosure, provided in the drawings, is not intended to limit the scope of the present disclosure for which protection is claimed, but only represents selected embodiments of the present disclosure. Based on the embodiments in the present disclosure, all other embodiments obtained by a person of ordinary skill in the art without inventive efforts shall fall within the scope of protection of the present disclosure.

It should be noted that similar symbols and letters denote similar items in the following drawings. Therefore, once an item has been defined in one of the drawings, it does not need to be further defined and explained in subsequent drawings.

In the description of the present disclosure, it should be noted that orientations or positional relationships indicated by terms, such as “up”, “down”, “inside”, and “outside”, “left”, etc., are the orientation or positional relationship based on the drawings, or the orientation or positional relationship that the product of the present disclosure is customarily placed in use, which are only to facilitate the description of the present disclosure and simplify the description, and are not to indicate or imply that the device or element referred to must have a particular orientation, or be constructed and operated with a particular orientation, and therefore cannot to be understood as limitations of the present disclosure.

Additionally, the terms “first” and “second”, etc., are used only to distinguish descriptions, and are not to be understood as indicating or implying a relative importance.

As disclosed in the background art, in the POP package bodies of the prior art, different package bodies are made of different materials, and CTE coefficients between materials are also different. During the reflow soldering process of the product, warpage of the product is likely to occur, which may result in bridging or false soldering between solder balls (intermediate layer solder balls and solder balls at the bottom of the substrate). Furthermore, in the POP package bodies of the prior art, a laser process is required to drill holes in the plastic package body. However, the laser can easily damage the bonding pad on the substrate surface, thereby causing the failure of the memory chip soldering.

Further, in the POP package bodies of the prior art, an adapter board structure is usually used for soldering. The solder balls need to be formed on the adapter plate, and the bonding pad on the substrate surface is soldered by the solder balls. However, the warpage is easily occurred on the substrate, which can easily cause bridging between the solder balls and affect the electrical connection. Furthermore, in conventional technology, the intermediate region between an upper layer and a lower layer is encapsulated by a molding process. Due to the small gap in the intermediate region, air cannot be expelled during the encapsulation, which results in insufficient filling. The formation of voids leads to a popcorn effect, thereby affecting the performance of the product.

In order to solve the above problems, the embodiments of the present disclosure provide a newly stacked package structure and a preparation method therefor. It is noted that features in embodiments in the present disclosure can be combined with each other without conflict.

Specifically, an objective of the present disclosure is to provide a stacked package structure and a preparation method therefor, which can reduce the warpage during the preparation process, improve the soldering effect, avoid bridging or false soldering, and ensure the electrical connection performance of the product. The encapsulation filling effect can be further improved to ensure the performance of the product.

In an aspect, the embodiments of the present disclosure provide a stacked package structure, including:
a first substrate;
a first chip, wherein the first chip is attached to the first substrate;
a second substrate, wherein the second substrate is spaced apart on one side of the first chip away from the first substrate; a bonding solder ball is arranged on one side of the second substrate close to the first substrate; and the bonding solder ball is connected to the first substrate; and
an encapsulation layer, wherein the encapsulation layer is arranged between the first substrate and the second substrate, and is coated outside the first chip and the bonding solder ball.

At least two sides of the first chip are arranged with the bonding solder balls; a first groove is arranged on one side of the first substrate close to the second substrate; a second groove is arranged on one side of the second substrate close to the first substrate; the first groove and the second groove are both located on one side of the bonding solder ball away from the first chip; and the encapsulation layer is filled into the first groove and the second groove.

In an optional embodiment, the first substrate includes a combined circuit layer and a first solder mask layer, wherein the first solder mask layer is arranged on one side of the combined circuit layer; the connection solder balls are arranged on the other side of the combined circuit layer; the first chip is attached to the first solder mask layer and is electrically connected to the combined circuit layer; and the first groove is arranged on the first solder mask layer and passes through the first solder mask layer, so that the encapsulation layer is in contact with the combined circuit layer.

In an optional embodiment, the second substrate includes an insulation layer, a second solder mask layer, and a third solder mask layer, wherein the second solder mask layer is arranged on one side of the insulation layer close to the first substrate; the third solder mask layer is arranged on one side of the insulation layer away from the first substrate; and the second groove is arranged on the second solder mask layer and at least partially passes through the second solder mask layer.

In an optional embodiment, the second groove corresponds to the first groove, and the second groove passes through the second solder mask layer and the insulation layer, so that the encapsulation layer is in contact with the third solder mask layer.

In an optional embodiment, the first groove and the second groove are staggered.

In an optional embodiment, a first extension groove is further arranged on the first solder mask layer, and a second extension groove is arranged on the second solder mask layer, wherein the first extension groove and the second extension groove are arranged in correspondence.

In an optional embodiment, a third groove is arranged on the third solder mask layer, and the third groove and the second extension groove are arranged in correspondence.

In an optional embodiment, the first solder mask layer is further thereon provided with a support window; the support window is therein provided with a support pad; and the support pad is provided with a heat dissipation post. The heat dissipation post extends in a direction away from the combined circuit layer and sequentially passes through the second solder mask layer, the insulation layer, and the third solder mask layer.

In an optional embodiment, the second solder mask layer is thereon provided with a first clearance opening; the insulation layer is thereon provided with a second clearance opening communicating with the first clearance opening; and the third solder mask layer is provided with a third clearance opening correspondingly communicating with the second clearance opening and a fourth clearance opening correspondingly communicating with the third clearance opening. Inner diameters of the first clearance opening, the second clearance opening, the third clearance opening, and the fourth clearance opening are all larger than an outer diameter of the heat dissipation post, and the heat dissipation post is in clearance fit with an inner wall of the first clearance opening, an inner wall of the second clearance opening, an inner wall of the third clearance opening, and an inner wall of the fourth clearance opening.

In an optional embodiment, an inner diameter D1 of the first clearance opening is larger than an inner diameter D2 of the second clearance opening, and an inner diameter D4 of the fourth clearance opening is larger than an inner diameter D3 of the third clearance opening.

In an optional embodiment, one end of the heat dissipation post away from the support pad is flush with a surface of one side of the third solder mask layer, away from the second solder mask layer.

In an optional embodiment, the second groove corresponds to the first groove; the second groove passes through the second solder mask layer, so that the encapsulation layer is in contact with the insulation layer; and the third groove is arranged on the third solder mask layer, wherein the third groove and the second groove are arranged in correspondence.

In an optional embodiment, multiple first grooves are provided; the third solder mask layer is further provided with a through hole; the through hole sequentially passes through the third solder mask layer, the insulation layer, and the second solder mask layer, corresponding to one of the first grooves; and the encapsulation layer is filled and extended to the through hole.

In an optional embodiment, a first pad is arranged on one side of the combined circuit layer away from the connection solder ball, and the first pad is embedded in the first solder mask and partially exposed to the first solder mask layer; and a second pad is arranged on a surface of one side of the second substrate provided with the second groove, and the bonding solder ball is arranged on the second pad and correspondingly connected to the first pad.

In an optional embodiment, the bonding solder ball includes an inner copper ball and an outer tin layer, wherein the outer tin layer is coated outside the inner copper ball and connected to the first pad and the second pad, respectively.

In an optional embodiment, the stacked package structure further includes a second chip, and the second chip is attached to one side of the second substrate away from the first substrate.

In an optional embodiment, a blocking groove is further arranged on one side of the second substrate away from the first substrate, and the blocking groove and the second groove are staggered.

In a second aspect, the embodiments of the present disclosure further provide a preparation method for the stacked package structure to prepare the foregoing stacked package structure. The preparation method includes:
providing a first substrate and a second substrate;
attaching a first chip to the first substrate;
attaching the second substrate to the first substrate, wherein the second substrate is spaced apart and arranged on one side of the first chip away from the first substrate; a bonding solder ball is arranged on one side of the second substrate close to the first substrate; and the bonding solder ball is connected to the first substrate; and
forming an encapsulation layer between the first substrate and the second substrate by encapsulation, wherein the encapsulation layer is coated outside the first chip and the bonding solder ball.

The bonding solder balls are arranged on at least two sides of the first chip; a first groove is arranged on one side of the first substrate close to the second substrate; a second groove is arranged on one side of the second substrate close to the first substrate; the first groove and the second groove are both located on one side of the bonding solder ball away from the first chip; and the encapsulation layer is filled into the first groove and the second groove.

In a third aspect, the embodiments of the present disclosure provide a preparation method for the stacked package structure, including:
forming a first groove on a surface of one side of the first substrate;
forming a second groove and a bonding solder ball on a surface of one side of the second substrate, wherein the second groove is located at an outer side of the bonding solder ball;
attaching a first chip on a surface of one side of the first substrate provided with the first groove;
attaching one side of the second substrate provided with the second groove to the first substrate, wherein the second substrate is spaced apart and arranged on one side of the first chip away from the first substrate; the bonding solder balls are connected to the first substrate and arranged on at least two sides of the first chip; and the first groove is located at an outer side of the bonding solder ball;
forming an encapsulation layer between the first substrate and the second substrate by encapsulation, wherein the encapsulation layer is coated outside the first chip and the bonding solder ball;
cutting the second substrate, the encapsulation layer, and the first substrate along the second groove; and
attaching a second chip on one side of the second substrate away from the first substrate.

In a fourth aspect, the embodiments of the present disclosure provide a stacked package structure, prepared by the foregoing preparation method, wherein the stacked package structure includes:
a first substrate;
a first chip, wherein the first chip is attached to a surface of one side of the first substrate;
a second substrate, wherein a bonding solder ball is arranged on a surface of one side of the second substrate; the second substrate is attached to the first substrate, and is spaced apart and arranged on one side of the first chip away from the first substrate; and the bonding solder balls are connected to the first substrate and arranged on at least two sides of the first chip;
an encapsulation layer, wherein the encapsulation layer is filled and formed between the first substrate and the second substrate, and is coated outside the first chip and the bonding solder ball; and
a second chip, wherein the second chip is attached to one side of the second substrate away from the first substrate.

The embodiments of the present disclosure include the following beneficial effects.

In the stacked package structure and preparation method therefor provided by the embodiments of the present disclosure, the first chip is attached to the first substrate; the second substrate is spaced apart on one side of the first chip away from the first substrate; the second substrate is connected to the first substrate by the bonding solder ball; and the encapsulation layer is formed between the first substrate and the second substrate. At least two sides of the first chip are provided with the bonding solder balls; the first groove and the second groove are respectively arranged on opposing surfaces of the first substrate and the second substrate; the first groove and the second groove are both located on one side of the bonding solder ball away from the first chip; and the encapsulation layer can be filled into the first groove and the second groove. Compared to the prior art, the embodiments of the present disclosure further design the first groove and the second groove, and the encapsulation layer is filled in the first groove and the second groove. On the one hand, it can enhance the bonding strength among the encapsulation layer, the first substrate, and the second substrate, and avoid the warpages of the first substrate and the second substrate during the reflow process, thereby ensuring the soldering effect, reducing the occurrence of bridging or the false soldering of the solder ball, and ensuring the electrical connection performance of the product. On the other hand, by designing the first groove and the second groove, the fluidity of the encapsulating material can be enhanced by the capillary phenomenon, so that the encapsulating material can be filled to the middle region between the first substrate and the second substrate, thereby providing a better filling effect, reducing voids, and ensuring the product performance.

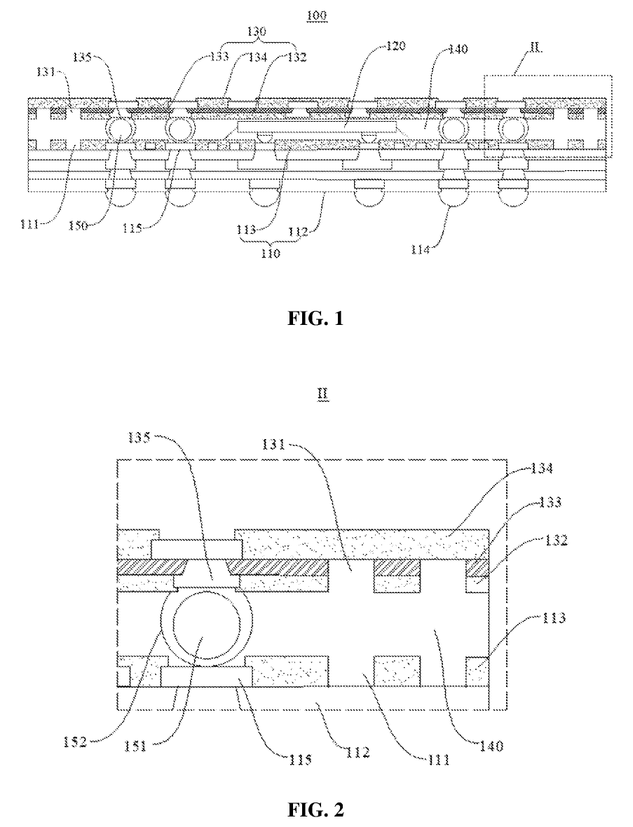

In one embodiment,
referring to FIGS. 1 and 2, the embodiments of the present disclosure provide a stacked package structure 100, which can reduce the warpage during the preparation process, improve the soldering effect, avoid bridging or false soldering, and ensure the electrical connection performance of the product. It can further improve the encapsulation filling effect and ensure the performance of the product.

The stacked package structure 100 provided by the embodiment of the present disclosure includes a first substrate 110, a first chip 120, a second substrate 130, and an encapsulation layer 140, wherein the first chip 120 is attached to the first substrate 110; the second substrate 130 is spaced apart on one side of the first chip 120 away from the first substrate 110; a bonding solder ball 150 is arranged on one side of the second substrate 130 close to the first substrate 110; the bonding solder ball 150 is connected to the first substrate 110; the encapsulation layer 140 is arranged between the first substrate 110 and the second substrate 130, and is coated outside the first chip 120 and the bonding solder ball 150. At least two sides of the first chip 120 are arranged with the bonding solder balls 150; a first groove 111 is arranged on one side of the first substrate 110 close to the second substrate 130; a second groove 131 is arranged on one side of the second substrate 130 close to the first substrate 110; the first groove 111 and the second groove 131 are both located on one side of the bonding solder ball 150 away from the first chip 120; and the encapsulation layer 140 is filled into the first groove 111 and the second groove 131.

During the actual preparation process, the first groove 111 and the second groove 131 are additionally provided, and the encapsulation layer 140 is filled in the first groove 111 and the second groove 131. On the one hand, it can enhance the bonding strength among the encapsulation layer 140, the first substrate 110, and the second substrate 130, avoid the warpage of the first substrate 110 and the second substrate 130 during the reflow process, ensure the soldering effect, reduce the occurrence of bridging or false soldering between the solder balls, and ensure the electrical connection performance of the product. On the other hand, by designing the first groove 111 and the second groove 131, the fluidity of the encapsulating material can be enhanced by capillary phenomenon, so that the encapsulating material can be filled into the center of the first substrate 110 and the second substrate 130, so as to provide a better filling effect, reduce voids, and ensure the product performance.

It is worth noting that the first chip 120 is flip-attached to the first substrate 110, and a filling adhesive layer is formed on the bottom of the first chip 120 by the dispensing process, thereby effectively protecting the soldering structure. The first chip 120 and the second substrate 130 are spaced apart to facilitate the flow of the encapsulating material. Furthermore, the first groove 111 and the second groove 131 herein can be rectangular grooves or circular grooves. The specific structures of the first groove 111 and the second groove 131 are not specifically limited herein.

In the embodiment, the first substrate 110 includes a combined circuit layer 112 and a first solder mask layer 113, wherein the first solder mask layer 113 is arranged on one side of the combined circuit layer 112; the connection solder balls 114 are arranged on the other side of the combined circuit layer 112; the first chip 120 is attached to the first solder mask layer 113 and is electrically connected to the combined circuit layer 112; and the first groove 111 is arranged on the first solder mask layer 113 and passes through the first solder mask layer 113, so that the encapsulation layer is in contact with the combined circuit layer 112. Specifically, the first substrate 110 can be a coreless substrate or a cored substrate. For example, it can be an epoxy glass fiber board, or an Ajinomoto build-up film, etc. In addition, the first substrate 110 can also be an organic substrate made of an organic material, such as a polyimide substrate. The combined circuit layer 112 can be a combination of a multilayer dielectric layer and a circuit layer. The dielectric layer material can be polyimide, the structure of which can be referred to prior circuit substrate constructions. The first solder mask layer 113 is a green coating layer, and the thickness of the first solder mask layer 113 is 5-30 μm. The connection solder balls 114 can be formed by a ball mounting process and electrically connected to the combined circuit layer 112.

Further, a first pad 115 is arranged on one side of the combined circuit layer 112 away from the connection solder ball 114, and the first pad 115 is embedded in the first solder mask 113 and partially exposed to the first solder mask layer 113; and a second pad 135 is arranged on a surface of one side of the second substrate 130 provided with the second groove 131, and the bonding solder ball 150 is arranged on the second pad 135 and correspondingly connected to the first pad 115. The first solder mask layer 113 is provided with a first window, the first window can be exactly exposed from the middle region of the first pad 115, and the bonding solder ball 150 can correspond to the first window, so as to correspondingly extend into the first window and electrically contact the first pad 115.

In the embodiment, the bonding solder ball 150 includes an inner copper ball 151 and an outer tin layer 152, wherein the outer tin layer 152 is coated outside the inner copper ball 151 and connected to the first pad 115 and the second pad 135. Specifically, the outer tin layer 152 can be completely coated outside the inner copper ball 151, and the preparation process can be referred to the existing double-layer solder ball structure. The inner copper ball 151 can be provided to enhance the support and reduce the flow of solder, thereby avoiding the bridging during soldering. Preferably, the inner copper ball 151 has a diameter of 180 μm and the outer tin layer 152 has an outer diameter of 220 μm.

In the embodiment, the second substrate 130 includes an insulation layer 133, a second solder mask layer 132, and a third solder mask layer 134, wherein the second solder mask layer 132 is arranged on one side of the insulation layer 133 close to the first substrate 110; the third solder mask layer 134 is arranged on one side of the insulation layer 133 away from the first substrate 110; and the second groove 131 is arranged on the second solder mask layer 132 and at least passes through the second solder mask layer 132. Specifically, the insulation layer 133 is further provided with a circuit layer; the second solder mask layer 132 is provided with the second pad 135; the third solder mask layer 134 is provided with a third pad; and the second pad 135 and the third pad are connected via the circuit layer. Preferably, the second solder mask layer 132 is provided with a second window; the second window is able to be correspondingly exposed from the second pad 135; and the third solder mask layer 134 is provided with a third window; and the third window is able to be correspondingly exposed from the third pad. Meanwhile, the bonding solder ball 150 can be accommodated in the second window and formed on the second pad 135.

It should be noted that the second substrate 130 can be a coreless substrate or a cored substrate. For example, it can be an epoxy glass fiber board, or an Ajinomoto build-up film, etc. Preferably, the second substrate 130 is a coreless substrate. The second solder mask layer 132 and the third solder mask layer 134 are also both green coating layers, and the first pad 115 and the second pad 135 are both embedded structures, which do not protrude from the solder mask layer, and therefore are different from the convex bonding pad structure in the traditional technology. The embedded structure can ensure solder bonding strength among the bonding pad, the first pad 115, and the second pad 135.

In the embodiment, the second groove 131 corresponds to the first groove 111, and the second groove 131 passes through the second solder mask layer 132 and the insulation layer 133, so that the encapsulation layer 140 is in contact with the third solder mask layer 134. Specifically, a plurality of first grooves 111 and a plurality of second grooves 131 are provided. The first grooves 111 and the second grooves 131 are in one-to-one correspondence, and the second grooves 131 penetrate into the third solder mask layer 134, which can further increase the depth of the second grooves 131, and further enhance the bonding strength between the encapsulation layer 140 and the second substrate 130. Moreover, the increased depth of the second grooves 131 can also further improve the fluidity of the encapsulating material during the encapsulation, which prevents insufficient filling of the encapsulant.

The embodiment of the present disclosure further provides a preparation method for the stacked package structure 100, which is used to prepare the foregoing stacked package structure. The preparation method includes the following steps: S1~S4.

S1: providing a first substrate 110 and a second substrate 130.

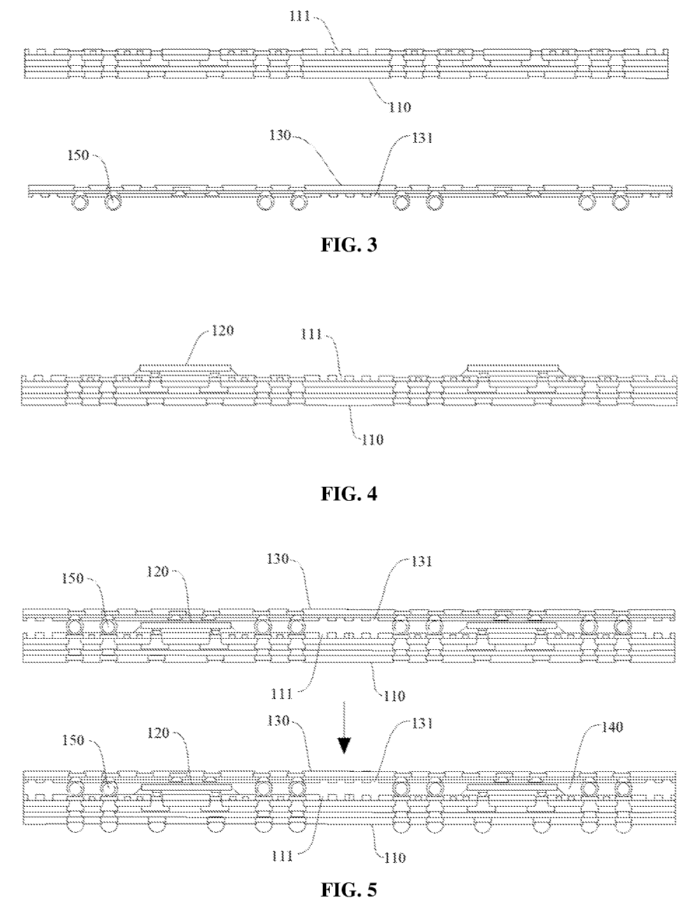

Referring to FIG. 3, specifically, the first substrate 110 and the second substrate 130 can be composed of materials such as epoxy glass fiber board or Ajinomoto build-up film, and the first substrate 110 and the second substrate 130 can both be coreless substrates or cored substrates. Preferably, the second substrate 130 is a coreless substrate, where the coreless substrate can be used to reduce the stack thickness.

The first substrate 110 can complete the preparation of the combined circuit layer and the first solder mask layer 113 in advance. After the second substrate 130 completes the preparation of the insulation layer 133, the second solder mask layer 132, and the third solder mask layer 134, the bonding solder balls 150 can be formed on one side of the second substrate 130 by using the ball mounting process.

It is noted that when the first substrate 110 and the second substrate 130 are prepared, the first groove 111 and the second groove 131 are also prepared at the same time.

S2: attaching a first chip 120 to the first substrate 110.

Referring to FIG. 4, specifically, the first chip 120 can be flip-attached to the first substrate 110, and the soldering part of the flip chip can be filled at the bottom by using the dispensing process, so as to form a filling adhesive layer for baking. The first chip 120 is attached to the chip attachment region of the first substrate 110, and the first groove 111 is arranged around the chip attachment region.

S3: attaching the second substrate 130 to the first substrate 110.

Referring to FIG. 5, specifically, one side of the second substrate 130 provided with the bonding solder ball 150 is attached to the first substrate 110, and the bonding solder ball 150 is connected to the first substrate 110. Moreover, the second substrate 130 is spaced apart on one side of the first chip 120 away from the first substrate 110, and a bonding solder ball 150 is arranged on one side of the second substrate 130 close to the first substrate 110. The bonding solder ball 150 is arranged around the first chip 120. The first groove 111 and the second groove 131 correspond with each other, and are all located on one side of the bonding solder ball 150 away from the first chip 120.

S4: forming an encapsulation layer 140 between the first substrate 110 and the second substrate 130 by encapsulation.

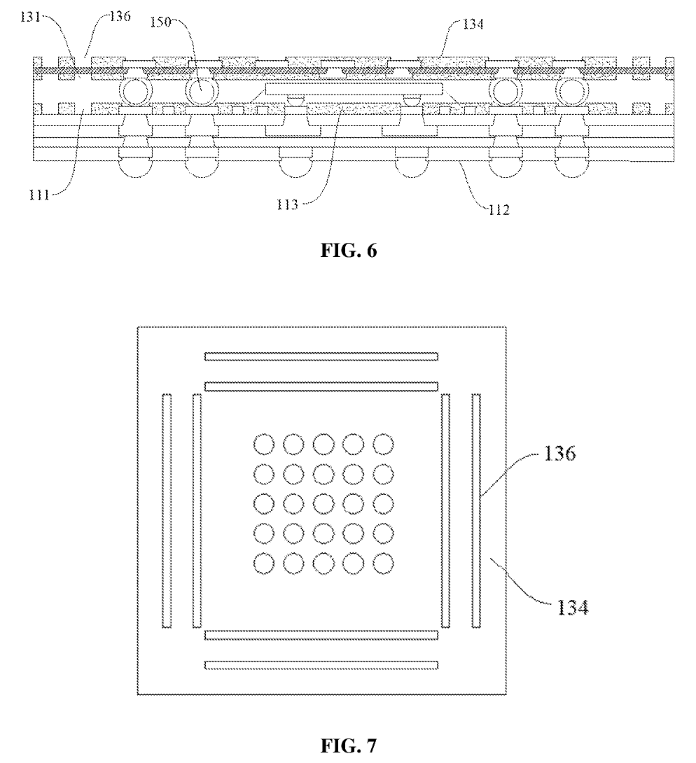

Referring to FIG. 6, specifically, the encapsulation layer 140 is coated outside the first chip 120 and the bonding solder ball 150, and the encapsulation layer 140 is filled into the first groove 111 and the second groove 131.

After completing the encapsulation, a connection solder ball 114 can be formed on the first substrate 110 again by using the ball mounting process, and a single product can be formed by using the cutting process.

In summary, in the stacked package structure 100 and preparation method therefor provided by the embodiments of the present disclosure, the first chip 120 is attached to the first substrate 110; the second substrate 130 is spaced apart on one side of the first chip 120 away from the first substrate 110; the second substrate 130 is connected to the first substrate 110 by the bonding solder ball 150; and the encapsulation layer 140 is formed between the first substrate 110 and the second substrate 130. At least two sides of the first chip 120 are arranged with the bonding solder balls 150, the opposing surfaces of the first substrate 110 and the second substrate 130 are respectively provided with a first groove 111 and a second groove 131, the first groove 111 and the second groove 131 are both located on one side of the bonding solder ball 150 away from the first chip 120, and the encapsulation layer 140 can be filled into the first groove 111 and the second groove 131. Compared to the prior art, the embodiments of the present disclosure further design the first groove 111 and the second groove 131, and the encapsulation layer 140 is filled in the first groove 111 and the second groove 131. On the one hand, it can enhance the bonding strength among the encapsulation layer 140, the first substrate 110, and the second substrate 130, avoid the warpage of the first substrate 110 and the second substrate 130 during the reflow process, ensure the soldering effect, reduce the occurrence of bridging or the false soldering of the solder ball, and ensure the electrical connection performance of the product. On the other hand, by designing the first groove 111 and the second groove 131, the fluidity of the encapsulating material can be enhanced by the capillary phenomenon, and therefore the encapsulating material can be filled to the center of the first substrate 110 and the second substrate 130, thereby providing a better filling effect, reducing voids, and ensuring the product performance.

In another embodiment, referring to FIGS. 6 and 7, the embodiments of the present disclosure provide a stacked package structure 100. The basic structure and principles thereof and the generated technical effects are the same as those in the above embodiment. For the purpose of a brief description, the portion of the embodiment is not mentioned, and reference can be made to the corresponding contents in the above embodiment.

In the embodiment,
the second groove 131 corresponds to the first groove 111; the second groove 131 passes through the second solder mask layer 132, so that the encapsulation layer 140 is in contact with the insulation layer 133; and the third groove 136 is arranged on the third solder mask layer 134, wherein the third groove 136 and the second groove 131 are arranged in correspondence. Specifically, the width of the third groove 136 is the same as that of the second groove 131, and the arrangement positions thereof correspond to each other. The insulation layer 133 acts as a structural support for the second substrate 130.

Further, in some specific application scenarios, after the product is manufactured, it needs to be cut. During cutting, the third groove 136 can be used as a cutting channel, thereby significantly reducing the cutting thickness, reducing cutting wear, and alleviating hidden solder joint cracking issues caused by cutting stress.

Specifically, during the preparation of the stacked package structure 100, the product can be cut along one third groove 136 after the encapsulation process, so as to obtain a single product.

It should be noted that the third groove 136 is a long strip-shaped structure and can be used as a subsequent cutting channel, so as to facilitate the cutting process. Moreover, multiple third grooves 136 and multiple second grooves 131 can be provided. During actual cutting, one of the third grooves 136 can be used as the cutting channel.

In the stacked package structure 100 provided by the embodiment, the third groove 136 is formed on the third solder mask layer 134 by cutting a groove, and the third groove 136 is used as a cutting channel. The third groove 136 passes through the third solder mask layer 134 and extends to the insulation layer 133, which results in a reduction in the cutting thickness during the actual cutting. This eliminates the need for separately designing a cutting channel in the traditional process, thereby improving the utilization rate of the second substrate 130. Further, the third grooves 136 and the second grooves 131 are corresponded with each other, which can significantly reduce the cutting thickness, reduce the cutting wear, reduce cutting stress, and alleviate solder joint latent crack issues caused by deformation of the bonding solder balls 150.

In one embodiment,

referring to FIG. 8, the embodiment of the present disclosure provides a stacked package structure 100, of which the basic structure and principles and the generated technical effects are the same as those in the above embodiments. For the purpose of a brief description, the portion of the embodiment is not mentioned; reference can be made to the corresponding contents in the above embodiments.

In the embodiment, the first groove 111 is arranged on one side of the first substrate 110 close to the second substrate 130; the second groove 131 is arranged on one side of the second substrate 130 close to the first substrate 110; the second groove 131 passes through the second solder mask layer 132 and the insulation layer 133, so that the encapsulation layer 140 is in contact with the third solder mask layer 134; and the first groove 111 and the second groove 131 are staggered.

Further, multiple first grooves 111 and multiple second grooves 131 are provided, and multiple first grooves 111 and multiple second grooves 131 are staggered. Preferably, on one side (such as the left side) of the bonding solder ball 150, the three first grooves 111 and the three second grooves 131 are provided. The three first grooves 111 and the three second grooves 131 are staggered, and two T-shaped structures can be formed. For example, an upper second groove 131 and two lower staggered first grooves 111 form a first T-shaped structure, and the remaining two upper second grooves 131 and a lower staggered first groove 111 form a second inverted T-shaped structure. By forming the T-shaped structures, the first grooves 111 and the second grooves 131 are exactly staggered and remain uniformly arranged.

It is noted that in the embodiment, both the first grooves 111 and the second grooves 131 are of the long strip-shaped groove structures.

By using the staggered first grooves 111 and second grooves 131, on the one hand, it can further enhance the bonding strength, so that the encapsulation layer 140 can extend and be filled into the first grooves 111 and the second grooves 131 in a staggered manner; and on the other hand, the warping stresses of the first substrate 110 and the second substrate 130 can be counteracted with each other. Moreover, the formation of the T-shaped distribution structure can provide multiple mold flow channels and enhance the fluidity of the middle region, thereby avoiding the popcorn effect caused by insufficient filling of the encapsulating material.

In one embodiment,

referring to FIG. 9, the embodiment provides a stacked package structure 100, of which the basic structure and principles and the generated technical effects are the same as those in the above embodiments. For the purpose of a brief description, the portion of the embodiment is not mentioned, reference can be made to the corresponding contents in the above embodiments.

In the embodiment, multiple first grooves 111 and multiple second grooves 131 are provided, and multiple first grooves 111 and multiple second grooves 131 are staggered. A first extension groove 116 is further arranged on the first solder mask layer 113, and a second extension groove 137 is arranged on the second solder mask layer 132, wherein the first extension groove 116 and the second extension groove 137 are arranged in correspondence. Specifically, the first extension groove 116 is spaced apart from the first groove 111, and the opening widths can be the same. The first extension groove 116 can be formed together with the first groove 111. The second extension groove 137 is spaced apart from the second groove 131, and the opening widths can be the same. The second extension groove 137 passes through the second solder mask layer 132, and the encapsulation layer 140 is filled into the first extension groove 116 and the second extension groove 137.

It should be noted that the staggered arrangement of the first grooves 111 and the second grooves 131 is also adopted in the embodiment. On the one hand, it can further enhance the bonding strength, so that the encapsulation layer 140 can extend and be filled into the first grooves 111 and the second grooves 131 in a staggered manner; and on the other hand, the warping stresses of the first substrate 110 and the second substrate 130 can be counteracted. Moreover, by forming the T-shaped structures, multiple mold flow channels can be provided to enhance the fluidity of the middle region, thereby avoiding the popcorn effect caused by insufficient filling of the encapsulating material.

Further, the third groove 136 is arranged on the third solder mask layer 134, and the third groove 136 and the second extension groove 137 are arranged in correspondence. Specifically, the second extension groove 137 does not pass through the insulation layer 133. The depth of the third groove 136 is less than or equal to the thickness of the third solder mask layer 134. Preferably, the depth of the third groove 136 is less than the thickness of the third solder mask layer 134. Therefore, the insulation layer 133 can be used as a support structure in the corresponding region of the second extension groove 137.

It should be noted that the third groove 136 here can be used as a cutting channel, so that the cutting depth during the actual cutting process is significantly reduced. This eliminates the need for separately designing a cutting channel in the traditional process, thereby improving the utilization rate of the second substrate 130. Further, the third grooves 136 and the second grooves 131 are corresponded with each other, which can significantly reduce the cutting thickness, reduce the cutting wear, reduce cutting stress, and alleviate solder joint latent crack issues caused by deformation of the bonding solder balls 150.

In one embodiment,

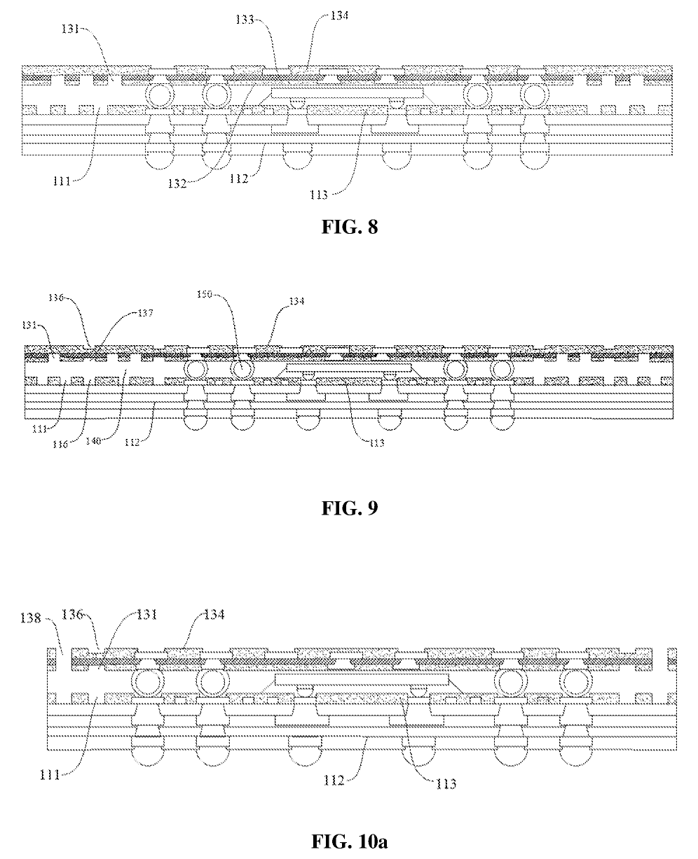

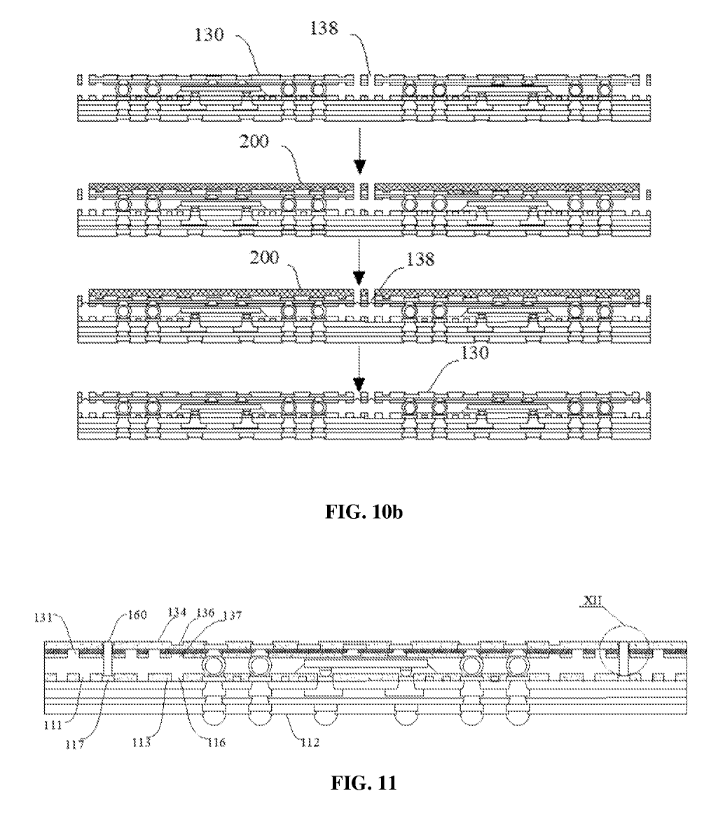

referring to FIG. 10a, the embodiment provides a stacked package structure 100, of which the basic structure, the principles, and the generated technical effects are the same as those in the above embodiments. For the purpose of a brief description, the portion of the embodiment is not mentioned, reference can be made to the corresponding contents in the above embodiments.

In the embodiment, the second groove 131 corresponds to the first groove 111; the second groove 131 passes through the second solder mask layer 132, so that the encapsulation layer 140 is in contact with the insulation layer 133; and the third groove 136 is arranged on the third solder mask layer 134, wherein the third groove 136 and the second groove 131 are arranged in correspondence. The third groove 136 is formed on the third solder mask layer 134 by cutting a groove, and the third groove 136 is used as a cutting channel, so as to reduce the cutting thickness during the actual cutting. This eliminates the need for separately designing a cutting channel in the traditional process, thereby improving the utilization rate of the second substrate 130. Further, the third grooves 136 and the second grooves 131 are corresponded with each other, which can significantly reduce the cutting thickness, reduce the cutting wear, reduce cutting stress, and alleviate solder joint latent crack issues caused by deformation of the bonding solder balls 150.

Further, multiple first grooves 111 are provided; the third solder mask layer 134 is further provided with a through hole 138; the through hole 138 sequentially passes through the third solder mask layer 134, the insulation layer 133, and the second solder mask layer 132, corresponding to one of the first grooves 111; and the encapsulation layer 140 is filled and extended into the through hole 138. Specifically, the through hole 138 can connect the region between the first substrate 110 and the second substrate 130 to the external space. During the encapsulation process, on one hand, the air in the region between the first substrate 110 and the second substrate 130 will be exhausted through the through hole 138, preventing the occurrence of voids, and further preventing the popcorn effect caused by insufficient filling of the encapsulating material. On the other hand, the encapsulating material extends to the through hole 138, which can further enhance the bonding strength between the second substrate 130 and the encapsulation layer 140.

Referring to FIG. 10b, during the actual preparation of the stacked package structure 100, after the second substrate 130 is attached, the encapsulant can be filled above the second substrate 130 by using a printing liquid encapsulating material. Specifically, a protective film 200 is attached to the surface of the second substrate 130, the through hole 138 can be exposed from the protective film 200, and the encapsulating material is filled by the printing encapsulation process. The encapsulating material can flow in from the through hole 138, and the protective film 200 can be removed after the encapsulation is completed.

In one embodiment,

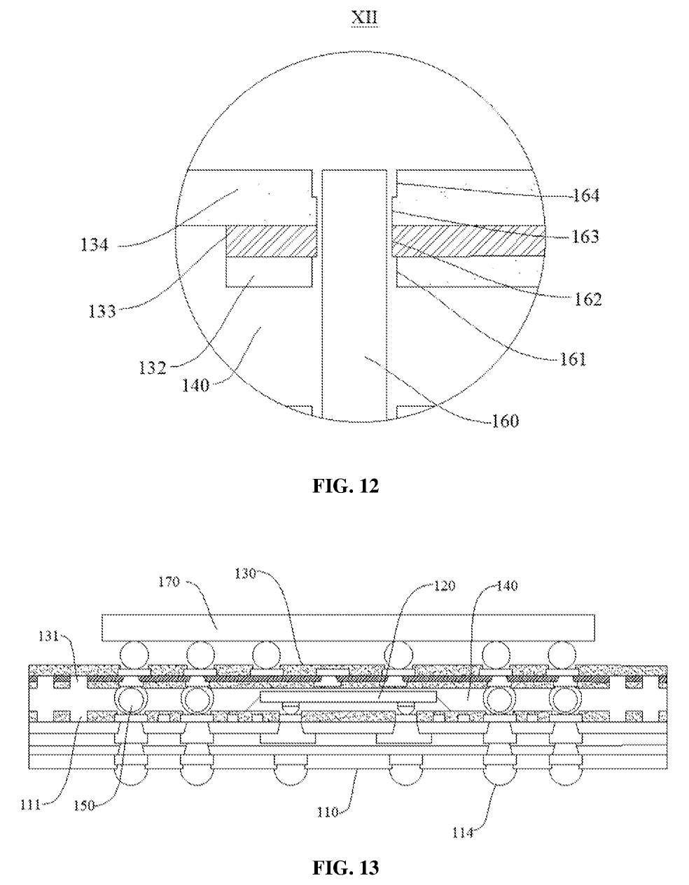

referring to FIGS. 11 and 12, the embodiment provides a stacked package structure 100, of which the basic structure, the principles, and the generated technical effects are the same as those in the above embodiments. For the purpose of a brief description, the portion of the embodiment is not mentioned, reference can be made to the corresponding contents in the above embodiments.

In the stacked package structure 100 provided by the embodiment of the present disclosure, the first solder mask layer 113 is further provided with a support window thereon; the support window is provided with a support pad 117 inside; and the support pad 117 is provided with a heat dissipation post 160, wherein the heat dissipation post 160 extends in a direction away from the combined circuit layer 112 and sequentially passes through the second solder mask layer 132, the insulation layer 133, and the third solder mask layer 134. Specifically, the heat dissipation post 160 can be a copper post. There is no electrical connection relationship between the support pad 117 and the combined circuit layer. The heat dissipation post 160 extends out of the second substrate 130. On the one hand, it can serve as a structural support, which improves the structural stability of the entire package structure; and on the other hand, the heat dissipation post 160 can serve as a heat dissipation structure during the encapsulant curing process or in subsequent processes, which reduces the impact of thermal process on the intermediate encapsulation layer 140.

In the embodiment, multiple first grooves 111 and multiple second grooves 131 are provided, and multiple first grooves 111 and multiple second grooves 131 are staggered. A first extension groove 116 is further arranged on the first solder mask layer 113, and a second extension groove 137 is arranged on the second solder mask layer 132, and the first extension groove 116 and the second extension groove 137 are arranged in correspondence. The third groove 136 is arranged on the third solder mask layer 134, and the third groove 136 and the second extension groove 137 are arranged in correspondence.

In the embodiment, the second solder mask layer 132 is thereon provided with a first clearance opening 161; the insulation layer 133 is thereon provided with a second clearance opening 162 communicating with the first clearance opening 161; and the third solder mask layer 134 is provided with a third clearance opening 163 correspondingly communicating with the second clearance opening 162 and a fourth clearance opening 164 correspondingly communicating with the third clearance opening 163, Inner diameters of the first clearance opening 161, the second clearance opening 162, the third clearance opening 163, and the fourth clearance opening 164 are all larger than an outer diameter of the heat dissipation post 160, and the heat dissipation post 160 is in clearance fit with an inner wall of the first clearance opening 161, an inner wall of the second clearance opening 162, an inner wall of the third clearance opening 163, and an inner wall of the fourth clearance opening 164.

It should be noted that the first clearance opening 161, the second clearance opening 162, the third clearance opening 163, and the fourth clearance opening 164 are all in clearance fit with the peripheral wall of the heat dissipation post 160. Therefore, the clearance can be used as an exhaust hole during the encapsulation process, so that the air in the intermediate layer can be expelled during the flow process of the encapsulating material. On the one hand, it improves the fluidity performance of the encapsulating material, and on the other hand, it avoids the void phenomenon. Specifically, the encapsulation process herein is a pressure injection process. During the pressure injection process, the air is expelled through the exhaust gap around the heat dissipation post 160, and the heat dissipation post 160 is used to guide the flow of the heat from the molding material, acting like a chimney to achieve both venting and heat dissipation.

It should be noted that the heat dissipation post 160 can be rectangular block-shaped, and the extension direction of the heat dissipation post 160 is in the same direction as the extension direction of the third groove 136. The rectangular block-shaped design, on the one hand, can expand the extension range, thereby expanding the heat dissipation area and enhancing the heat dissipation capability, and on the other hand, it can also expand the gap range of the peripheral wall of the heat dissipation post 160, so that the air in the intermediate layer can be rapidly expelled, and the exhaust capacity can be improved.

It also needs to be noted that since the heat dissipation post 160 is in clearance fit with the second substrate 130, the heat dissipation post 160 can be used as a positioning structure when attaching the second substrate 130, thereby ensuring the accurate positioning of the second substrate 130, avoiding the offsetting of the bonding solder balls 150 when attaching the second substrate 130, and improving the precision of attaching and soldering.

In the embodiment, an inner diameter D1 of the first clearance opening 161 is larger than an inner diameter D2 of the second clearance opening 162, and an inner diameter D4 of the fourth clearance opening 164 is larger than an inner diameter D3 of the third clearance opening 163. Specifically, the first clearance opening 161, the second clearance opening 162, the third clearance opening 163, and the fourth clearance opening 164 are arranged in sequence from bottom to top, and the entire structure is small in the middle and large at both ends, which ensures the smooth mounting of the heat dissipation post 160.

Further, one end of the heat dissipation post 160 away from the support pad 117 is flush with a surface of one side of the third solder mask layer 134 away from the second solder mask layer 132.

In summary, in the stacked package structure 100 provided by the embodiment, through the design of the heat dissipation post 160 and the clearance opening, on the one hand, it can improve the heat dissipation effect and reduce the impact of thermal process on the intermediate layer, and one the other hand, during the encapsulation process, the air in the intermediate layer can be expelled through the gaps around the heat dissipation post 160, avoiding bubble or void phenomenon. Meanwhile, the design of the heat dissipation post 160 can also ensure the attaching accuracy of the second substrate 130.

In one embodiment,

referring to FIG. 13, the embodiment of the present disclosure provides a stacked package structure 100, of which the basic structure, the principles, and the generated technical effects are the same as those in the above embodiments. For the purpose of a brief description, the portion of the embodiment is not mentioned, reference can be made to the corresponding contents in the above embodiments.

In the embodiment, the stacked package structure 100 includes the first substrate 110, the first chip 120, the second substrate 130, the encapsulation layer 140, and a second chip 170. The first chip 120 is attached to the first substrate 110; the second substrate 130 is spaced apart on one side of the first chip 120 away from the first substrate 110; a bonding solder ball 150 is arranged on one side of the second substrate 130 close to the first substrate 110; the bonding solder ball 150 is connected to the first substrate 110; the encapsulation layer 140 is arranged between the first substrate 110 and the second substrate 130, and is coated outside the first chip 120 and the bonding solder ball 150. At least two sides of the first chip 120 are provided with the bonding solder balls 150; a first groove 111 is arranged on one side of the first substrate 110 close to the second substrate 130; a second groove 131 is arranged on one side of the second substrate 130 close to the first substrate 110; the first groove 111 and the second groove 131 are both located on one side of the bonding solder ball 150 away from the first chip 120; and the encapsulation layer 140 is filled into the first groove 111 and the second groove 131. The second chip 170 is attached to one side of the second substrate 130 away from the first substrate 110, and the second chip 170 can be a module chip or a memory chip.

In one embodiment,

the embodiment of the present disclosure provides a preparation method for the stacked package structure 100, of which the basic steps, the principles, and the generated technical effects are the same as those in the above embodiments. For the purpose of a brief description, the portion of the embodiment is not mentioned, reference can be made to the corresponding contents in the above embodiments.

The preparation method provided by the embodiment includes steps S1~S3.

S1: forming a first groove 111 on a surface of one side of the first substrate 110.

Referring to FIG. 3, specifically, the first substrate 110 is first prepared, and a first groove 111 is formed around the chip attachment region of the first substrate 110.

S2: forming a second groove 130 and a bonding solder ball 150 on a surface of one side of the second substrate 131.

Referring to FIG. 3, specifically, the second substrate 130 is prepared; a second groove 131 is formed on a surface of one side of the second substrate 130, the bonding solder ball 150 is formed by a ball mounting process, and the second groove 131 is located outside the bonding solder ball 150.

It should be noted that the first substrate 110 and the second substrate 130 in this embodiment can also adopt relevant constructions, such as those in the above embodiments, which are equally capable of realizing the preparation method.

S3: attaching a first chip 120 on a surface of one side of the first substrate 110 provided with the first groove 111.

Referring to FIG. 4, specifically, the first chip 120 is flip-attached to the chip attachment region of the first substrate 110, and the soldering part of the flip chip can be filled at the bottom by using the dispensing process, so as to form a filling adhesive layer for baking. The first chip 120 is attached to the chip attachment region of the first substrate 110, and the first groove 111 is arranged around the chip attachment region.

S4: attaching one side of the second substrate 130 provided with the second groove 131 to the first substrate 110.

Referring to FIG. 5, the second substrate 130 is spaced apart on one side of the first chip 120 away from the first substrate 110; the bonding solder balls 150 are connected to the first substrate 110 and arranged on at least two sides of the first chip 120; and the first groove 111 is located at an outer side of the bonding solder ball 150. Specifically, one side of the second substrate 130 provided with the bonding solder ball 150 is attached to the first substrate 110, and the bonding solder ball 150 is connected to the first substrate 110. Moreover, the second substrate 130 is spaced apart and arranged on one side of the first chip 120 away from the first substrate 110, a bonding solder ball 150 is arranged on one side of the second substrate 130 close to the first substrate 110, and the bonding solder ball 150 is arranged around the first chip 120. The first grooves 111 and the second grooves 131 correspond with each other, and are all located on one side of the bonding solder ball 150 away from the first chip 120.

S5: forming an encapsulation layer 140 between the first substrate 110 and the second substrate 130 by encapsulation.

Referring to FIG. 5, the encapsulation layer 140 is coated outside the first chip 120 and the bonding solder ball 150, and the encapsulation layer 140 is filled to the first grooves 111 and the second grooves 131.

S6: cutting the second substrate 130, the encapsulation layer 140, and the first substrate 110 along the second groove 131.

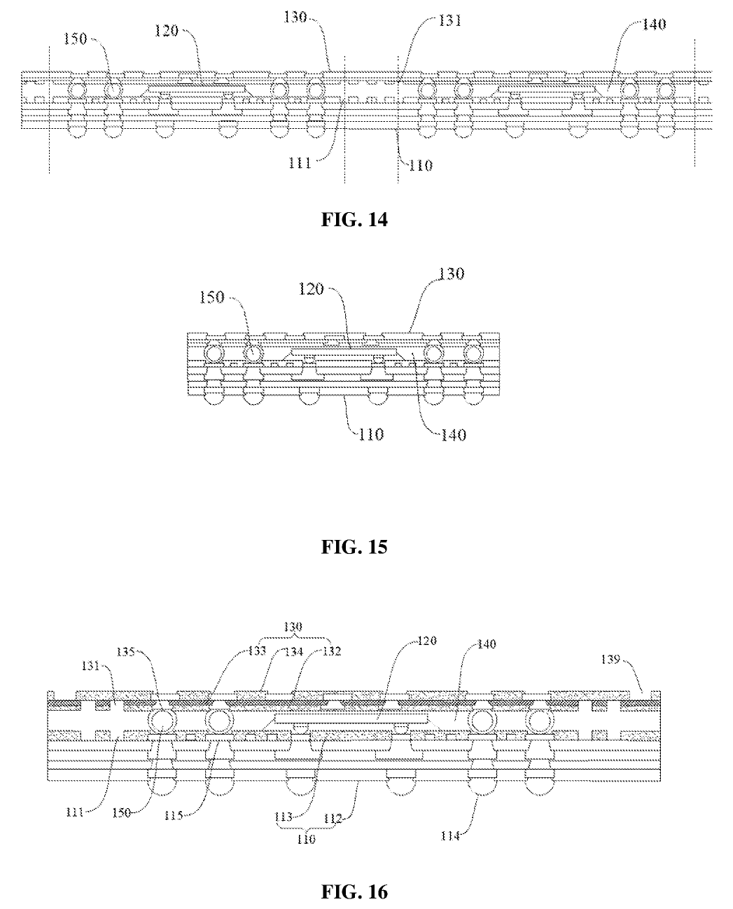

Referring to FIG. 14, specifically, the second substrate 130, the encapsulation layer 140, and the first substrate 110 can be cut in sequence along the cutting channel overlapping with the second groove 131, so as to obtain a single product.

Referring to FIG. 15, the embodiments of the present disclosure provide a stacked package structure 100, which is prepared by using the foregoing preparation method. The basic structure, the principles, and the generated technical effects are the same as those in the above embodiments. For the purpose of a brief description, the portion of the embodiment is not mentioned, reference can be made to the corresponding contents in the above embodiments.

The stacked package structure 100 provided by the embodiment of the present disclosure includes a first substrate 110, a first chip 120, a second substrate 130, and an encapsulation layer 140. The first chip 120 is attached to a surface of one side of the first substrate 110; the bonding solder ball 150 is arranged on a surface of one side of the second substrate 130; the second substrate 130 is attached to the first substrate 110 and spaced apart on one side of the first chip 120 away from the first substrate 110; the bonding solder balls 150 are connected to the first substrate 110 and arranged on at least two sides of the first chip 120; and the encapsulation layer 140 is filled between the first substrate 110 and the second substrate 130, and is coated outside the first chip 120 and the bonding solder balls 150.

In one embodiment,

referring to FIG. 16, the embodiment of the present disclosure provides a stacked package structure 100, of which the basic structure, the principles, and the generated technical effects are the same as those in the above embodiments. For the purpose of a brief description, the portion of the embodiment is not mentioned, reference can be made to the corresponding contents in the above embodiments.

In the embodiment, the stacked package structure 100 includes the first substrate 110, the first chip 120, the second substrate 130, and the encapsulation layer 140. The first chip 120 is attached to the first substrate 110; the second substrate 130 is spaced apart on one side of the first chip 120 away from the first substrate 110; a bonding solder ball 150 is arranged on one side of the second substrate 130 close to the first substrate 110; the bonding solder ball 150 is connected to the first substrate 110; the encapsulation layer 140 is arranged between the first substrate 110 and the second substrate 130, and is coated outside the first chip 120 and the bonding solder ball 150. At least two sides of the first chip 120 are arranged with the bonding solder balls 150; a first groove 111 is arranged on one side of the first substrate 110 close to the second substrate 130; a second groove 131 is arranged on one side of the second substrate 130 close to the first substrate 110; the first groove 111 and the second groove 131 are both located on one side of the bonding solder ball 150 away from the first chip 120; and the encapsulation layer 140 is filled into the first groove 111 and the second groove 131.

Further, a blocking groove 139 is further arranged on one side of the second substrate 130 away from the first substrate 110, wherein the blocking groove 139 and the second groove 131 are staggered, and the blocking groove 139 does not pass through the second substrate 130. Preferably, the blocking groove 139 is provided on the surface of the third solder mask layer 134, and the blocking groove 139 passes through the third solder mask layer 134. Further, the blocking groove 139 is further arranged outside the second groove 131, so as to facilitate its removal together with the groove during cutting.

During the process of forming the encapsulation layer 140, a part of the encapsulating material will creep along the edge side and extend to the edge region of the second substrate 130. By providing the blocking groove 139, the part of the encapsulating material creeping along the edge side can be effectively accommodated, thereby preventing the encapsulating material from creeping along the edge side wall to the middle part of the surface of the second substrate 130, and avoiding the encapsulating material from affecting the circuit region.

The above description is only specific embodiments of the present disclosure, and the protection scope of the present disclosure is not limited thereto. Any variations or substitutions that may be readily conceived by those skilled in the art within the technical scope disclosed herein should fall within the protection scope of the present disclosure. Therefore, the protection scope of the present disclosure shall be defined by the scope of the claims.

### INDUSTRIAL APPLICABILITY

In the stacked package structure and preparation method therefor provided by the embodiments of the present disclosure, the first chip is attached to the first substrate; the second substrate is spaced apart on one side of the first chip away from the first substrate; the second substrate is connected to the first substrate by the bonding solder ball; and the encapsulation layer is formed between the first substrate and the second substrate. At least two sides of the first chip are provided with the bonding solder balls; the first groove and the second groove are respectively arranged on opposing surfaces of the first substrate and the second substrate; the first groove and the second groove are both located on one side of the bonding solder ball away from the first chip; and the encapsulation layer can be filled into the first groove and the second groove. Compared to the prior art, the embodiments of the present disclosure further design the first groove and the second groove, and the encapsulation layer is filled in the first groove and the second groove. On the one hand, it can enhance the bonding strength among the encapsulation layer, the first substrate, and the second substrate, and avoid the warpages of the first substrate and the second substrate during the reflow process, thereby ensuring the soldering effect, reducing the occurrence of bridging or the false soldering of the solder ball, and ensuring the electrical connection performance of the product. On the other hand, by designing the first groove and the second groove, the fluidity of the encapsulating material can be enhanced by the capillary phenomenon, so that the encapsulating material can be filled to the middle region between the first substrate and the second substrate, thereby providing a better filling effect, reducing voids, and ensuring the product performance.

Furthermore, it will be appreciated that the stacked package structure and the preparation method therefor provided by the embodiments of the present disclosure are reproducible, and can be applied in a variety of industrial applications. For example, the stacked package structure and the preparation method thereof provided by embodiments of the present disclosure can be applied in the technical field of chip packaging.

1. A stacked package structure, comprising:
a first substrate;
a first chip, wherein the first chip is attached to the first substrate;
a second substrate, wherein the second substrate is spaced apart and arranged on one side of the first chip away from the first substrate; a bonding solder ball is arranged on one side of the second substrate close to the first substrate; and the bonding solder ball is connected to the first substrate; and
an encapsulation layer, wherein the encapsulation layer is arranged between the first substrate and the second substrate, and is coated outside the first chip and the bonding solder ball, wherein
at least two sides of the first chip are provided with the bonding solder balls; a first groove is arranged on one side of the first substrate close to the second substrate; a second groove is arranged on one side of the second substrate close to the first substrate; the first groove and the second groove are both located on one side of the bonding solder ball away from the first chip; and the encapsulation layer is filled into the first groove and the second groove.

2. The stacked package structure according to claim 1, wherein the first substrate comprises a combined circuit layer and a first solder mask layer; the first solder mask layer is arranged on one side of the combined circuit layer; a connection solder ball is arranged on the other side of the combined circuit layer; the first chip is attached to the first solder mask layer and is electrically connected to the combined circuit layer; and the first groove is arranged on the first solder mask layer and passes through the first solder mask layer, so that the encapsulation layer is in contact with the combined circuit layer.

3. The stacked package structure according to claim 2, wherein the second substrate comprises an insulation layer, a second solder mask layer, and a third solder mask layer; the second solder mask layer is arranged on one side of the insulation layer close to the first substrate; the third solder mask layer is arranged on one side of the insulation layer away from the first substrate; and the second groove is arranged on the second solder mask layer and at least passes through the second solder mask layer.

4. The stacked package structure according to claim 3, wherein the second groove corresponds to the first groove, and the second groove passes through the second solder mask layer and the insulation layer, so that the encapsulation layer is in contact with the third solder mask layer.

5. The stacked package structure according to claim 4, wherein the first groove and the second groove are staggered.

6. The stacked package structure according to claim 5, wherein a first extension groove is further arranged on the first solder mask layer, a second extension groove is arranged on the second solder mask layer, and the first extension groove and the second extension groove are arranged in correspondence.

7. The stacked package structure according to claim 6, wherein a third groove is arranged on the third solder mask layer, and the third groove and the second extension groove are arranged in correspondence.

8. The stacked package structure according to claim 3, wherein the first solder mask layer is further provided with a support window thereon; the support window is therein provided with a support pad; the support pad is provided with a heat dissipation post; and the heat dissipation post extends in a direction away from the combined circuit layer and sequentially passes through the second solder mask layer, the insulation layer, and the third solder mask layer.

9. The stacked package structure according to claim 8, wherein the second solder mask layer is thereon provided with a first clearance opening; the insulation layer is thereon provided with a second clearance opening communicating with the first clearance opening; the third solder mask layer is thereon provided with a third clearance opening correspondingly communicating with the second clearance opening and a fourth clearance opening correspondingly communicating with the third clearance opening; inner diameters of the first clearance opening, the second clearance opening, the third clearance opening, and the fourth clearance opening are all larger than an outer diameter of the heat dissipation post; and the heat dissipation post is in clearance fit with an inner wall of the first clearance opening, an inner wall of the second clearance opening, an inner wall of the third clearance opening, and an inner wall of the fourth clearance opening.

10. The stacked package structure according to claim 9, wherein an inner diameter D1 of the first clearance opening is larger than an inner diameter D2 of the second clearance opening, and an inner diameter D4 of the fourth clearance opening is larger than an inner diameter D3 of the third clearance opening.

11. The stacked package structure according to claim 8, wherein one end of the heat dissipation post away from the support pad is flush with a surface of one side of the third solder mask layer away from the second solder mask layer.

12. The stacked package structure according to claim 3, wherein the second groove corresponds to the first groove; the second groove passes through the second solder mask layer, so that the encapsulation layer is in contact with the insulation layer; and a third groove is arranged on the third solder mask layer, wherein the third groove and the second groove are arranged in correspondence.

13. The stacked package structure according to claim 12, wherein multiple first grooves are provided; the third solder mask layer is further provided with a through hole; the through hole sequentially passes through the third solder mask layer, the insulation layer, and the second solder mask layer, and corresponds to one of the first grooves; and the encapsulation layer is filled and extended to the through hole.

14. The stacked package structure according to claim 2, wherein a first pad is arranged on one side of the combined circuit layer away from the connection solder ball, and the first pad is embedded in the first solder mask and partially exposed to the first solder mask layer; and a second pad is arranged on a surface of one side of the second substrate provided with the second groove, and the bonding solder ball is arranged on the second pad and correspondingly connected to the first pad.

15. The stacked package structure according to claim 14, wherein the bonding solder ball comprises an inner copper ball and an outer tin layer; and the outer tin layer is coated outside the inner copper ball and connected to the first pad and the second pad, respectively.

16. The stacked package structure according to claim 1, wherein the stacked package structure further comprises a second chip, the second chip is attached to one side of the second substrate away from the first substrate.

17. The stacked package structure according to claim 1, wherein a blocking groove is further arranged on one side of the second substrate away from the first substrate, and the blocking groove and the second groove are staggered.

18. A preparation method for a stacked package structure, applied to prepare the stacked package structure according to claim 1, wherein the preparation method comprises:
providing the first substrate and the second substrate;
attaching the first chip to the first substrate;
attaching the second substrate to the first substrate, wherein the second substrate is spaced apart and arranged on one side of the first chip away from the first substrate; the bonding solder ball is arranged on one side of the second substrate close to the first substrate, and the bonding solder ball is connected to the first substrate; and
forming an encapsulation layer between the first substrate and the second substrate by encapsulation, wherein the encapsulation layer is coated outside the first chip and the bonding solder ball, wherein
at least two sides of the first chip are arranged with the bonding solder balls; the first groove is arranged on one side of the first substrate close to the second substrate; the second groove is arranged on one side of the second substrate close to the first substrate; the first groove and the second groove are both located on one side of the bonding solder ball away from the first chip; and the encapsulation layer is filled into the first groove and the second groove.

19. A preparation method of a stacked package structure, comprising:
forming a first groove on a surface of one side of a first substrate;
forming a second groove and a bonding solder ball on a surface of one side of a second substrate, wherein the second groove is located at an outer side of the bonding solder ball;
attaching a first chip on a surface of one side of the first substrate provided with the first groove;
attaching one side of the second substrate provided with the second groove to the first substrate, wherein the second substrate is spaced apart and arranged on one side of the first chip away from the first substrate; the bonding solder ball is connected to the first substrate and arranged on at least two sides of the first chip; and the first groove is located at an outer side of the bonding solder ball;
forming an encapsulation layer between the first substrate and the second substrate by encapsulation, wherein the encapsulation layer is coated outside the first chip and the bonding solder ball; and
cutting the second substrate, the encapsulation layer, and the first substrate along the second groove.

20. A stacked package structure, prepared by the preparation method according to claim 18, wherein the stacked package structure comprises:
a first substrate;
a first chip, wherein the first chip is attached to a surface of one side of the first substrate;
a second substrate, wherein a bonding solder ball is arranged on a surface of one side of the second substrate; the second substrate is attached to the first substrate, and is spaced apart and arranged on one side of the first chip away from the first substrate; and the bonding solder ball is connected to the first substrate and arranged on at least two sides of the first chip; and
an encapsulation layer, wherein the encapsulation layer is filled and formed between the first substrate and the second substrate, and is coated outside the first chip and the bonding solder ball.
